(19) United States
(12) Patent Application Publication
(10) Pub. No.: US 2007/0110261 A1
(43) Pub. Date: May 17, 2007

(54) AUDIO PROCESSING SYSTEM WITH FUNCTION OF AUTOMATIC GAIN CONTROL AND METHOD THEREOF

(75) Inventors: Kuan-Hong Hsieh, Shenzhen, Guangdong (CN); Wen-Chuan Lian, Shenzhen, Guangdong (CN); Wen-Sheng Tsai, Shenzhen, Guangdong (CN); Xiao-Guang Li, Shenzhen, Guangdong (CN); Zai-An Pan, Shenzhen, Guangdong (CN)

Correspondence Address: NORTH AMERICA INTELLECTUAL PROPERTY CORPORATION, P.O. BOX 506, MERRIFIELD, VA, 22116, US

(73) Assignee: HON HAI PRECISION INDUSTRY CO., LTD., Taipei Hsien (TW)

(21) Appl. No.: 11/558,426

(22) Filed: Nov. 9, 2006

(30) Foreign Application Priority Data
Nov. 11, 2005 (CN) 200510101233.1

(51) Int. Cl. H03G 3/00

(52) U.S. Cl. 381/104; 381/107

(57) ABSTRACT

The present invention provides an audio processing system with function of automatic gain control and method thereof. The method includes steps of: adjusting the default gain value to an adjusted gain value in response to a gain adjusting command; signaling a gain amplifier to amplify analog audio signals received from a digital/analog converter by the adjusted gain value; updating the default gain value with the adjusted gain value; updating the time period corresponding to a new current time thereby yielding an updated time period; reading a predetermined gain value referenced by the updated time period; calculating an integrated gain value according to the predetermined gain value referenced by the updated time period and the adjusted gain value; and updating the predetermined gain value referenced by the updated time period with the integrated gain value, thereby audio energy of the analog audio signals amplified is proper to a user's hearing.

### BACKGROUND OF THE INVENTION

1. Field of the Invention

The present invention relates to an audio processing system with function of automatic gain control and method thereof, especially to an audio processing system with function of automatic gain control according to a time period to which a current time belongs and method thereof.

2. Description of Related Art

Compared to before, there is a significant increase of the work pace and living pace of people. Living in a fast pace society often puts a person under high pressure, thus more easily become discontent. Enjoying music has become one of the most common activity to relax and relieve the high pressure and people are often seen enjoying music while working, commuting, and when resting.

In addition, people generally have regular working schedules and living habits. I.e, the time a person wakes up, works, eats, sleeps, exercises, and so on usually remains somewhat habitual. A person may enjoy listening to different style of music when waking up, working, exercising . . . etc. For example, while at work, a person may prefer to listen to light music at a low volume and listen to music with a fast beat while exercising. Additionally, a person's hearing sensitivity may change according to different time periods of the day. During morning hours, a person's listening sensitivity may be more sensitive after waking up, and less sensitive in the afternoon.

Therefore, what is needed is an system capable of automatically controlling a gain value corresponding to different times of the day, which can automatically play appropriate music at a suitable volume during different time period, thereby making it convenient for people to enjoying music. Especially to drivers that listen music simultaneously, the system can lower the risks of accidents of the people who manually adjust the music volume while driving. Furthermore, if a listener prefers enjoying music at a desired volume corresponding to certain time periods of the day, for example, while waking up, the listener can wake up to soothing music comfortably.

Therefore, a heretofore unaddressed need exists in the industry to overcome the aforementioned deficiencies and inadequacies.

### SUMMARY OF THE INVENTION

In order to solve said problems, the present invention provides an audio processing system with function of automatic gain control and method thereof. The audio processing system automatically adjusts a gain value of a gain amplifier according to a time period to which a current time belongs, thereby audio energy of analog audio signals amplified by the gain amplifier is proper to a user's hearing.

The audio processing system includes a storage unit, a processing unit, a decoding unit, a digital/analog converter and a gain managing unit. The storage unit stores a default gain value, a plurality of audio files and a gain setting table, the gain setting table being configured for listing a plurality of time period each referencing a predetermined gain value. The processing unit fetches an audio file from the storage unit after receiving a playing command for playing the audio file. The decoding unit decodes the audio file fetched to generate digital audio signals. The digital/analog converter converts the digital audio signals to analog audio signals. The gain managing unit includes a time processing module, an obtaining module, an updating module and a gain adjusting module. The time processing module reads a current time from a timer and determining a time period corresponding to the current time. The obtaining module reads a predetermined gain value referenced by the time period in the gain setting table. The updating module updates the default gain value with the predetermined gain value referenced by the time period. The gain adjusting module signals a gain amplifier to amplify the analog audio signals received from the digital/analog converter by the predetermined gain value referenced by the time period.

The audio processing system includes a storage unit, a processing unit, a decoding unit and a digital/analog converter. The storage unit stores a default gain value, a plurality of audio files and a gain setting table, the gain setting table being configured for listing a plurality of time period each referencing a predetermined gain value. The processing unit fetches an audio file from the storage unit after receiving a playing command for playing the audio file. The decoding unit decodes the audio file fetched to generate digital audio signals. The digital/analog converter converts the digital audio signals to analog audio signals. The processing unit includes a time processing module, an obtaining module, an updating module and a gain adjusting module. The time processing module reads a current time from a timer and determining a time period corresponding to the current time. The obtaining module reads a predetermined gain value referenced by the time period in the gain setting table. The updating module updates the default gain value with the predetermined gain value referenced by the time period. The gain adjusting module signals a gain amplifier to amplify the analog audio signals received from the digital/analog converter by the predetermined gain value referenced by the time period.

The automatic gain control method includes the steps of: receiving a gain adjusting command for adjusting the default gain value; adjusting the default gain value to an adjusted gain value; signaling a gain amplifier to amplify analog audio signals received from a digital/analog converter by the adjusted gain value; updating the default gain value with the adjusted gain value; updating the time period corresponding to a new current time thereby yielding an updated time period; reading a predetermined gain value referenced by the updated time period in the gain setting table; calculating an integrated gain value according to the predetermined gain value referenced by the updated time period and the adjusted gain value; and updating the predetermined gain value referenced by the updated time period in the gain setting table with the integrated gain value.

Other systems, methods, features, and advantages will be or become apparent to one with skill in the art upon examination of the following drawings and detailed description. It is intended that all such additional systems, methods, features, and advantages be included within this description, be within the scope of the present invention, and be protected by the accompanying claims.

### BRIEF DESCRIPTION OF THE DRAWINGS

FIG. 1 is a block diagram of a hardware infrastructure of an audio processing system in accordance with a preferred embodiment of the present invention;

FIG. 2 is a schematic diagram of main function modules of a gain managing unit of FIG. 1;

FIG. 3 is a flowchart of a preferred automatic gain control method by utilizing the audio processing system of FIG. 1;

FIG. 4 is a flowchart of a preferred method of regenerating a predetermined gain value referenced by a time period by utilizing the audio processing system of FIG. 1;

FIG. 5 is a block diagram of a hardware infrastructure of an audio processing system in accordance with an alternative preferred embodiment of the present invention; and

FIG. 6 is a schematic diagram of main function modules of a processing unit of FIG. 5.

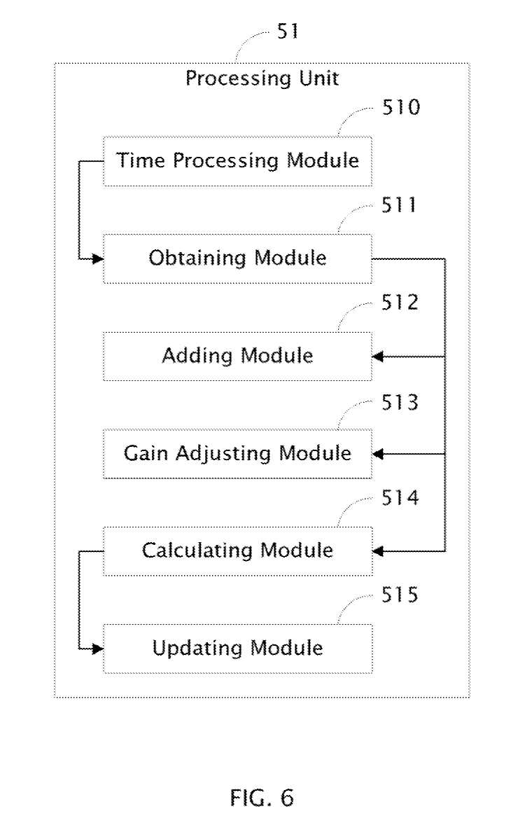

### DETAILED DESCRIPTION OF THE INVENTION

The automatic gain control function of the present invention can be incorporated in an audio processing system, such as a car stereo system and other electric device. The other electric device includes an MP3 (Moving Picture Experts Group Audio Layer 11) player, an electronic book, a mobile telephone, a radio, a television set, and so on. The following detailed description of preferred embodiments is made with reference to the attached drawings.

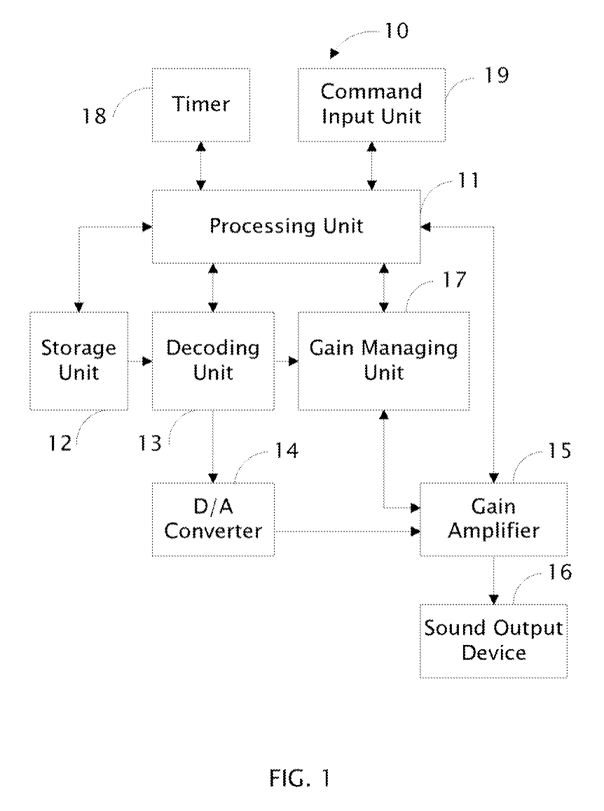

FIG. 1 is a block diagram of a hardware infrastructure of the audio processing system 10 in accordance with the preferred embodiment of the present invention. The audio processing system 10 includes a processing unit 11, a storage unit 12, a decoding unit 13, a digital/analog (D/A) converter 14, a gain amplifier 15, a sound output device 16, a timer 18, and a command input unit 19.

The storage unit 12 stores a plurality of audio files, a default gain value of the gain amplifier 15, a decoding program, and a gain setting table. The gain setting table lists a plurality of time periods each referencing a predetermined gain value. The storage unit 12 can be a flash storage, a hard disk, and the like. The processing unit 11 controls components of the system 10. The processing unit 11 can be a digital signal processor (DSP), a central processing unit (CPU), and the like.

The command input unit 19 generates control commands after receiving operational inputs. The control commands include a playing command and a gain adjusting command for playing an audio file and for signaling the gain amplifier 15 to adjusting a gain value respectively thereof. After receiving the playing command, the processing unit 11 fetches/reads the audio file from the storage unit 12.

The decoding unit 13 invokes the decoding program stored in the storage unit 12, decodes the audio files fetched to generate digital audio signals. The D/A converter 14 converts the digital audio signals received from the decoding unit 13 to analog audio signals.

The gain amplifier 15 amplifies the analog audio signals received from the D/A converter 14 by the default gain value stored in the storage unit 12. The sound output device 16 produces sounds corresponding to the analog audio signals amplified by the gain amplifier 15. The sound output device 16 can be an earphone or a speaker.

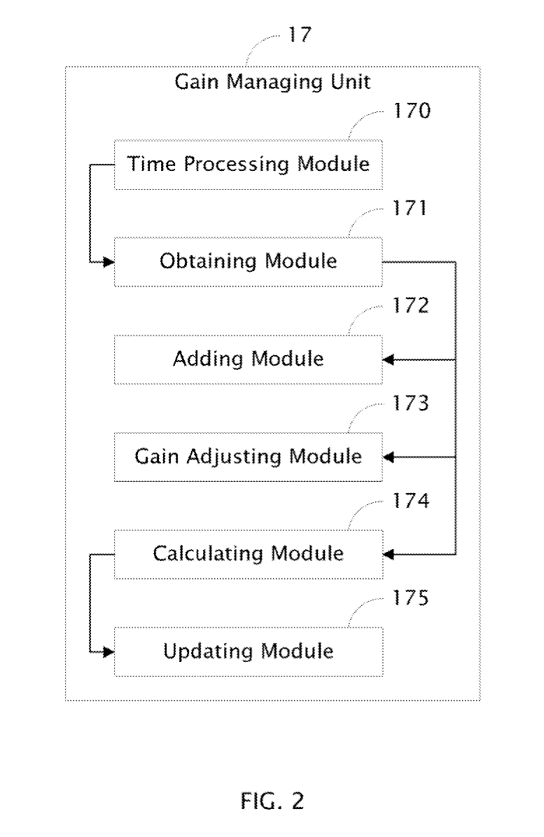

The audio processing system 10 further includes a gain managing unit 17 integrated with the processing unit 11. Referring to FIG. 2, the gain managing unit 17 includes a time processing module 170, an obtaining module 171, an adding module 172, a gain adjusting module 173, a calculating module 174, and an updating module 175.

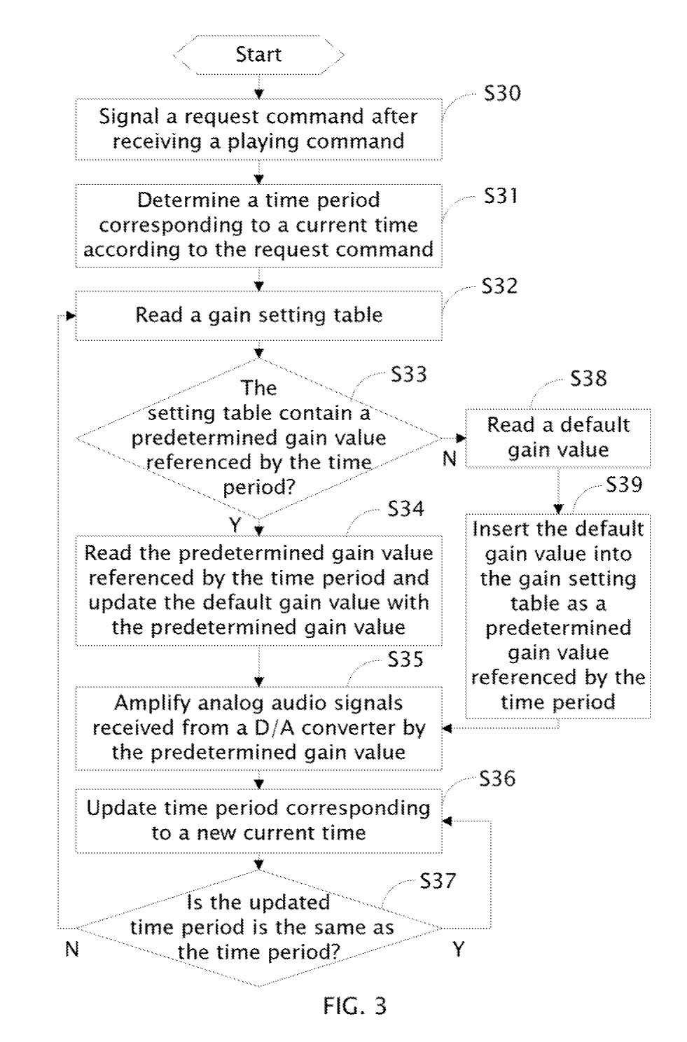

FIG. 3 is a flowchart of a preferred automatic gain control method by utilizing the audio processing system 10 of FIG. 1. Referring to FIG. 2, in step S30, the processing unit 11 signals a request command to the gain managing unit 17 after receiving the playing command.

In step S31, the time processing module 170 determines a time period corresponding to a current time obtained from the timer 18.

In step S32, the obtaining module 171 reads the gain setting table stored in the storage unit 12.

In step S33, the obtaining module 171 determines whether the gain setting table contains a predetermined gain value referenced by the time period determined by the time processing module 170.

If the gain setting table does not contain the predetermined gain value referenced by the time period, in step S38, the obtaining module 171 reads the default gain value stored in the storage unit 12 as a current gain value.

In step S39, the adding module 172 inserts the default gain value into the gain setting table as the predetermined gain value referenced by the time period, and then the procedure goes to step S35.

In step S33, if the gain setting table contains the predetermined gain value referenced by the time period, in step S34, the obtaining module 171 reads the predetermined gain value referenced by the time period in the gain setting table, and the updating module 175 updates the default gain value stored in the storage unit 12 with the predetermined gain value referenced by the time period.

In step S35, the gain adjusting module 173 signals the gain amplifier 15 to amplify the analog audio signals received from D/A converter 14 by the predetermined gain value.

In step S36, the time processing module 170 updates the time period corresponding to a new current time obtained from the timer 18 thereby yielding an updated time period.

In step S37, the time processing module 170 determines whether the updated time period is the same as the time period.

If the updated time period is to the same as the time period, the procedure goes to step S36; otherwise, the procedure goes to step S32. The step S32 to step S37 is performed recursively until the audio signal processing system 10 is turned-off.

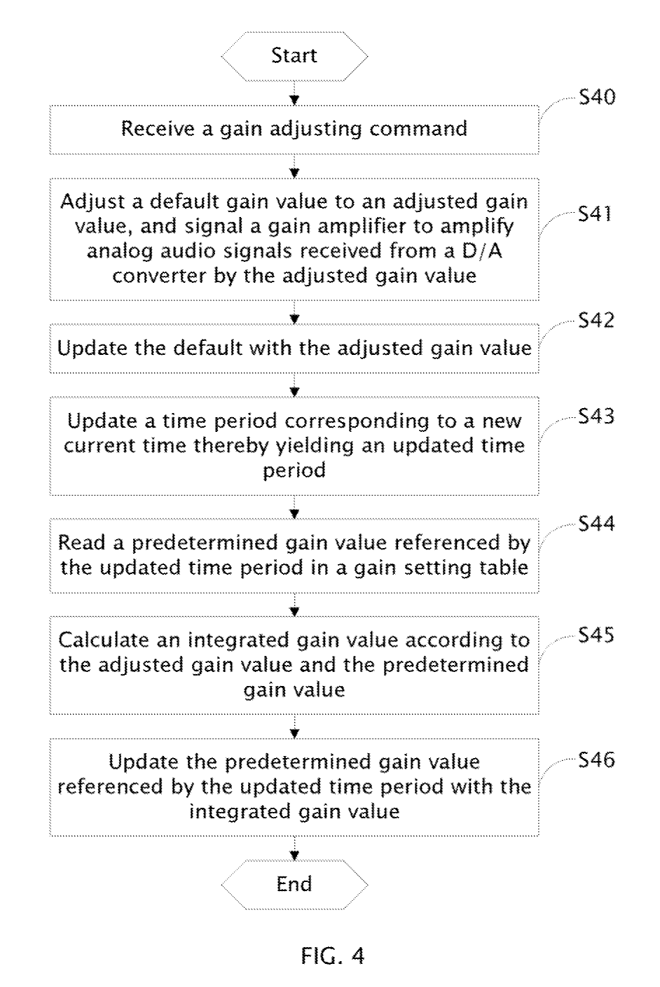

FIG. 4 is a flowchart of a preferred method of retrieving the predetermined gain value referenced by the time period by utilizing the audio processing system 10 of FIG. 1. Referring to FIG. 2, in step S40, the gain managing unit 17 receives the adjusting command for adjusting the default gain value.

In step S41, the gain adjusting module 173 adjusts the default gain value stored in the storage unit 12 to an adjusted gain value, and signals the gain amplifier 15 to amplify the analog audio signals received from the D/A converter 14 by the adjusted gain value.

In step S42, the updating module 175 updates the default gain value stored in the storage unit 12 with the adjusted gain value.

In step S43, the time processing module 170 updates the time period corresponding to a new current time obtained from the timer 18 thereby yielding an updated time period.

In step S44, the obtaining module 171 reads the predetermined gain value referenced by the updated time period.

In step S45, the calculating module 174 assigns a weight value to the predetermined gain value and the adjusted gain value correspondingly, multiplies the predetermined gain value and the adjusted gain value by the weight value assigned correspondingly, thereby obtaining two products, and totals the two products to obtain an integrated gain value.

In step S46, the updating module 175 updates the predetermined gain value referenced by the updated time period in the gain setting table with the integrated gain value.

In an alternative embodiment, the updating module 175 directly updates the predetermined gain value referenced by the time period in the gain setting table with the adjusted gain value.

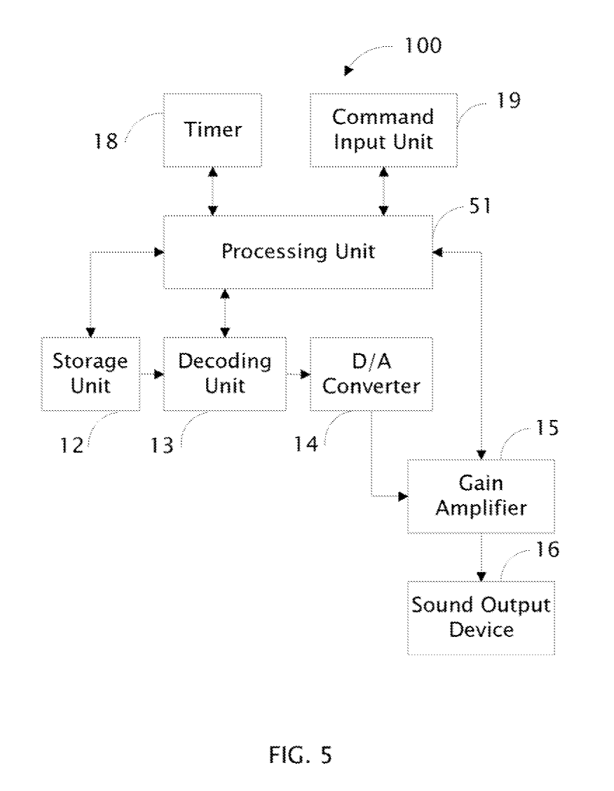

FIG. 5 is a block diagram of a hardware infrastructure of an audio processing system 100 in accordance with an alternative embodiment of the present invention. The audio processing system 100 of the alternative embodiment is the same as that of the preferred embodiment, except that the gain managing unit 17 is integrated in the processing unit 51.

Therefore, in this alternative embodiment, the processing unit 51 further has the function as well as the gain managing unit 17 does in FIG. 1. That is, the processing unit 51 has a time processing module 510, an obtaining module 511, an adding module 512, a gain adjusting module 513, a calculating module 514, and an updating module 515, which respectively performs the same functions as the time processing module 170, an obtaining module 171, an adding module 172, a gain adjusting 173, a calculating module 174, and an updating module 175 of the gain managing unit 17.

It is understood that the invention may be embodied in other forms without departing from the spirit thereof. Thus, the present examples and embodiments are to be considered in all respects as illustrative and not restrictive, and the invention is not to be limited to the details given herein.

What is claimed is:

1. An audio processing system comprising:
a storage unit for storing a default gain value, a plurality of audio files and a gain setting table, the gain setting table being configured for listing a plurality of time period each referencing a predetermined gain value;
a processing unit for fetching an audio file from the storage unit after receiving a playing command for playing the audio file;
a decoding unit for decoding the audio file fetched to generate digital audio signals;
a digital/analog converter for converting the digital audio signals to analog audio signals; and
a gain managing unit comprising:
a time processing module for reading a current time from a timer and determining a time period corresponding to the current time;
an obtaining module for reading a predetermined gain value referenced by the time period in the gain setting table;
an updating module for updating the default gain value with the predetermined gain value referenced by the time period; and
a gain adjusting module for signaling a gain amplifier to amplify the analog audio signals received from the digital/analog converter by the predetermined gain value referenced by the time period.

2. The audio processing system according to claim 1, wherein the gain managing unit further comprises an adding module, the adding module inserts the default gain value into the gain setting table as the predetermined gain value referenced by the time period, if the gain setting table does not contain the predetermined gain value referenced by the time period.

3. The audio processing system according to claim 1, wherein the gain managing unit further comprises a calculating module which calculates an integrated gain value according to the predetermined gain value referenced by the time period and an adjusted gain value, after the default gain value is adjusted to the adjusted gain value, and then the updating module updates the predetermined gain value referenced by the time period in the gain setting table with the integrated gain value.

4. The audio processing system according to claim 3, wherein the calculating module assigns a weight value respectively to the predetermined gain value referenced by the time period and the adjusted gain value, multiplies the predetermined gain value referenced by the time period and the adjusted gain value by the corresponding weight value assigned, thereby obtaining two products, and totals the two products to obtain the integrated gain value.

5. The audio processing system according to claim 1, wherein the updating module updates the predetermined gain value referenced by the time period in the gain setting table with an adjusted gain value, after the default gain value is adjusted to the adjusted gain value.

6. An audio processing system with a function of automatic gain control, the system comprising:
a storage unit for storing a default gain value, a plurality of audio files and a gain setting table, the gain setting table being for listing a plurality of time periods each referencing a predetermined gain value;
a processing unit for fetching an audio file from the storage unit after receiving a playing command for playing the audio file;
a decoding unit for decoding the audio file fetched to generate digital audio signals; and
a digital/analog converter for converting the digital audio signals to analog audio signals;
wherein the processing unit comprises:
a time processing module for reading a current time from a timer and determining a time period corresponding to the current time;
an obtaining module for reading a predetermined gain value referenced by the time period in the gain setting table;
an updating module for updating the default gain value with the predetermined gain value referenced by the time period; and
a gain adjusting module for signaling a gain amplifier to amplify the audio signals received from the digital/analog converter by the predetermined gain value referenced by the time period.

7. The audio processing system according to claim 6, wherein the processing unit further comprises an adding module, the adding module inserts the default gain value into the gain setting table as the predetermined gain value referenced by the time period, if the gain setting table does not contain the predetermined gain value referenced by the time period.

8. The audio processing system according to claim 6, wherein the processing unit further comprises a calculating module, the calculating module calculates an integrated gain value according to the predetermined gain value referenced by the time period and an adjusted gain value, after the default gain value is adjusted to the adjusted gain value, and then the updating module updates the predetermined gain value referenced by the time period in the gain setting table with the integrated gain value.

9. The audio processing system according to claim 8, wherein the calculating module assigns a weight value respectively to the predetermined gain value referenced by the time period and the adjusted gain value, multiplies the predetermined gain value referenced by the time period and the adjusted gain value by the corresponding weight value assigned, thereby obtaining two products, and totals the two products to obtain the integrated gain value.

10. The audio processing system according to claim 6, wherein the updating module updates the predetermined gain value referenced by the time period in the gain setting table with an adjusted gain value, after a default gain value is adjusted to the adjusted gain value.

11. An automatic gain control method, the method comprising steps of:
receiving a playing command for playing an audio file;
reading a current time and determining a time period corresponding to the current time;
reading a predetermined gain value referenced by the time period in a gain setting table stored in a storage unit;
updating a default gain value stored in the storage unit with the predetermined gain value referenced by the time period; and
signaling a gain amplifier to amplify analog audio signals received from a digital/analog converter by the predetermined gain value referenced by the time period.

12. The method according to claim 11, further comprising steps of:
reading the default gain value, and
inserting the default gain value into the gain setting table as the predetermined gain value referenced by the time period, if the gain setting table does not contain the predetermined gain value referenced by the time period.

13. The method according to claim 1, further comprising steps of:
receiving a gain adjusting command for adjusting the default gain value;
adjusting the default gain value to an adjusted gain value;
signaling a gain amplifier to amplify analog audio signals received from a digital/analog converter by the adjusted gain value;
updating the default gain value with the adjusted gain value; updating the time period corresponding to a new current time thereby yielding an updated time period;
reading a predetermined gain value referenced by the updated time period in the gain setting table;
calculating an integrated gain value according to the predetermined gain value referenced by the updated time period and the adjusted gain value; and
updating the predetermined gain value referenced by the updated time period in the gain setting table with the integrated gain value.

14. The method according to claim 13, further comprising steps of:
assigning a weight value respectively to the predetermined gain value referenced by the time period and the adjusted gain value;
multiplying the predetermined gain value referenced by the time period and the adjusted gain value by the corresponding weight value assigned, thereby obtaining two products; and
totalling the two products to obtain the integrated gain value.

15. The method according to claim 1, further comprising a step of updating the predetermined gain value referenced by the time period in the gain setting table with an adjusted gain value, after the default gain value is adjusted to the adjusted gain value.
